(19) United States
(12) Patent Application Publication
(10) Pub. No.: US 2009/0257522 A1
(43) Pub. Date: Oct. 15, 2009

(54) COMMUNICATION APPARATUS

(75) Inventor: Akira KUWANO, Kanagawa (JP)

Correspondence Address: YOUNG & THOMPSON, 209 Madison Street, Suite 500, ALEXANDRIA, VA, 22314, US

(73) Assignee: NEC ELECTRONICS CORPORATION, Kanagawa (JP)

(21) Appl. No.: 12/420,246

(22) Filed: Apr. 8, 2009

(30) Foreign Application Priority Data
Apr. 10, 2008 (JP) 2008-102652

(51) Int. Cl. H03C 5/00; H04B 7/02

(52) U.S. Cl. 375/267; 375/269

(57) ABSTRACT

An exemplary aspect of an embodiment of the present invention is a communication apparatus including an amplifier circuit which adjusts transmit power of a first signal and transmit power of a second signal if the transmit power of the first signal having a first frequency included in a first frequency band is different from the transmit power of the second signal having a second frequency included in a second frequency band, where the second frequency is different from the first frequency. The amplifier circuit includes a variable inductor which varies an inductance value for each of the first signal and the second signal to adjust the transmit power of the first signal and the transmit power of the second signal.

### BACKGROUND

1. Field of the Invention

The present invention relates to a communication device including a transmit amplifier, and particularly to a communication device including a transmit amplifier for wideband digital wireless communications.

2. Description of Related Art

In recent years, the technique to integrate 3 Ghz to 10 GHz band high frequency wireless communication system, which is used in Ultra Wide Band (UWB) communication system or the like, into one chip has been developing. In such wideband wireless communication, it is desired to realize a transmit amplifier capable of smooth transmit power transfer in wideband. Such a transmit amplifier is especially useful in a multiband OFDM system for UWB. The reason for this is explained below.

In UWB multiband OFDM system (hereinafter merely referred to as UWB), each frequency band occupies 528 MHz band to realize a high-speed transmission of maximum 480 Mbps. An effective throughput and a communication propagation distance can be improved by hopping three frequency bands.

On the other hand, in a wideband system like UWB, the communication propagation distance deteriorates by a generation of a frequency deviation in the transmit power as shown in FIG. 5. The reason for this is explained below. In UWB, an average maximum transmit power must be limited to less than or equal to −41.3 dBm/MHz. Therefore, when hopping three frequency bands, an average transmit power of a frequency band with the highest transmit power must be suppressed to less than or equal to −36.5 dBm/MHz considering the incidence of ⅓. A frequency deviation causes to reduce the average transmit power and thereby leading to shorten the communication propagation distance. For example, in case of FIG. 5, the average transmit power deteriorates by 2.3 dB as compared to the possible average transmit power, and the communication propagation distance decreases by about ¾. Therefore, it is desired to realize a technology to suppress the propagation distance from deteriorating by smoothing the transmit power.

FIG. 6 is a block diagram depicting a transmit amplifier disclosed by Japanese Unexamined Patent Application Publication No. 11-074803. As depicted in FIG. 6, an intermediate frequency (IF) signal is a local frequency of a local frequency oscillator 2, which is set by a frequency setting circuit 1. The IF signal is set to a carrier frequency by a mixer 3. A transmit signal which is set to the carrier frequency passes through a variable attenuator 4 and is branched by a brancher 5. One of the branched transmit signals is output as a transmission output, and another is input to a detector 6. A detection voltage Vd detected by the detector 6 is input to a differential amplifier 8 via a loop filter 7. The output Vd of the detector 6 is input also to a differential amplifier 9. The differential amplifier 9 generates a correction voltage from detection voltages Vf0 at a carrier frequency f0, which is a preset standard and Vd.

This correction voltage is input to a holding circuit 10. In response to a frequency setting signal fset, the holding circuit 10 samples an output of the differential amplifier 9 and outputs it. Further, the holding circuit 10 holds the value until the frequency is changed next time. An adder 11 adds the correction voltage output from the holding circuit 10 and a reference voltage Vr which sets the transmission output. An output of the adder 11 is to be an output setting voltage for correcting a variation of the detection voltage caused by a frequency change. This output setting voltage is input to the differential amplifier 8 as a comparison voltage.

The differential amplifier 8 outputs a control voltage so that the detection voltage is to be equal to the output setting voltage to control the amount of attenuation of the variable attenuator 4. This enables to keep the transmit power constant even if the frequency is changed.

### SUMMARY

The inventor has found a problem that the transmit amplifier disclosed by Japanese Unexamined Patent Application Publication No. 11-074803 has a large circuit size. This is because that the transmit amplifier requires the detector 6, the two differential amplifiers 8 and 9, the loop filter 7, the adder 11, the holding circuit 10 and the variable attenuator 4. Especially the differential amplifiers 8 and 9 and the loop filter 7 have large areas, thereby leading to increase the circuit size as a whole. In light of a whole circuit, the circuit disclosed by Japanese Unexamined Patent Application Publication No. 11-074803 has a large circuit size for detecting the transmit output and adjust it. Further, the circuit disclosed by Japanese Unexamined Patent Application Publication No. 11-074803 has a problem that it consumes a large amount of power. This is because that the detector 6, the two differential amplifiers 8 and 9, the loop filter 7, the adder 11, the holding circuit 10 and the variable attenuator 4 always consume power. As the variable attenuator 4 attenuates the power of a signal to be transmitted, a large amount of power is consumed also when transmitting a signal after adjusting the transmit power. Therefore, it is desired to achieve a circuit configuration which can adjust the power of a transmit signal without attenuating a transmit signal by an attenuator.

An exemplary aspect of an embodiment of the present invention is a communication apparatus including an amplifier circuit which adjusts transmit power of a first signal and transmit power of a second signal if the transmit power of the first signal having a first frequency included in a first frequency band is different from the transmit power of the second signal having a second frequency included in a second frequency band, where the second frequency is different from the first frequency. The amplifier circuit includes a variable inductor which varies an inductance value for each of the first signal and the second signal to adjust the transmit power of the first signal and the transmit power of the second signal.

The present invention provides a communication device with a simple circuit configuration with low power consumption having a wideband transmit amplifier which prevents from deteriorating the communication propagation distance.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a block diagram illustrating the configuration of a transmit amplifier according to a first exemplary embodiment of the present invention;

FIG. 2 illustrates a transmission gain characteristic variations within one frequency band according to the first exemplary embodiment of the present invention;

FIG. 3 is a block diagram illustrating the configuration of a transmit amplifier according to a second exemplary embodiment of the present invention;

FIG. 4 is illustrates a UWB frequency band according to the second exemplary embodiment of the present invention;

FIG. 5 illustrates a case when there is a deviation between frequency bands in a transmit power at the time of frequency hopping in UWB multiband OFDM system; and

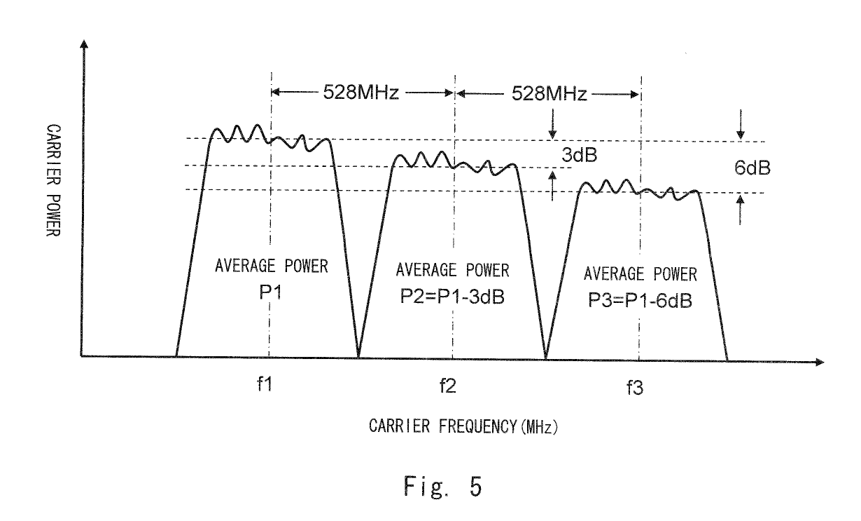

FIG. 6 is a block diagram illustrating a transmit amplifier disclosed by Japanese Unexamined Patent Application Publication No. 11-074803.

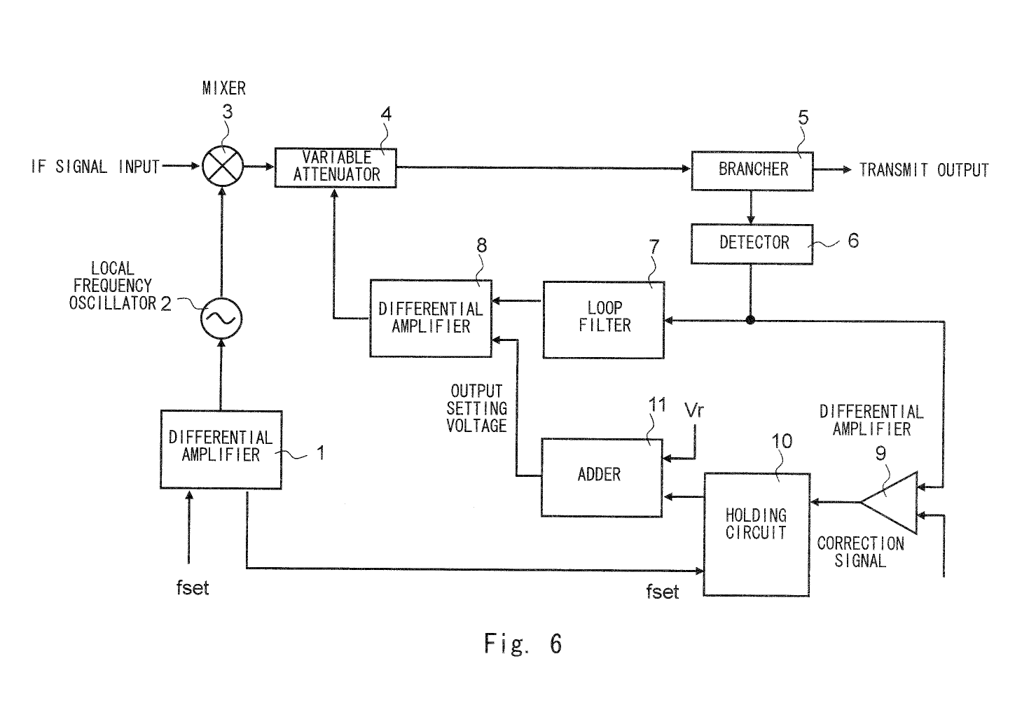

### DETAILED DESCRIPTION OF THE EXEMPLARY EMBODIMENTS

### First Exemplary Embodiment

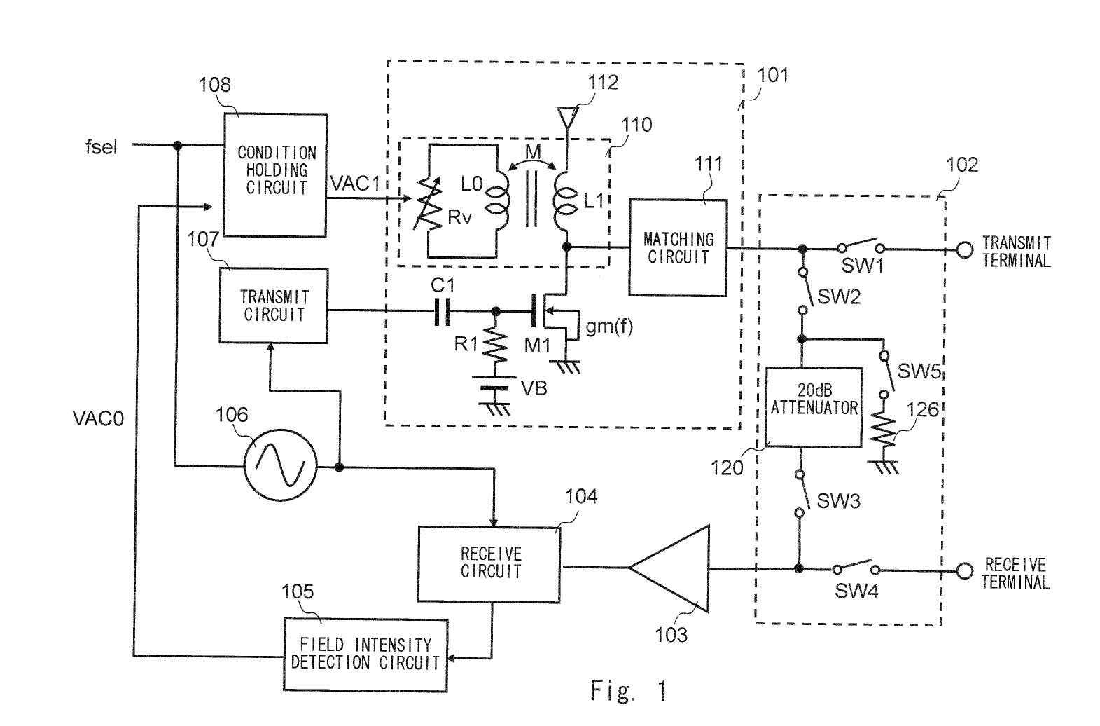

Hereafter, embodiments of the present invention is described with reference to the drawings. FIG. 1 is a block diagram illustrating a transmit/receive circuit for UWB including a transmit circuit according to a first exemplary embodiment of the present invention. This circuit has a wideband transmit amplifier section 101, a loopback circuit section 102 for providing a signal back to a detector circuit in order to detect transmit power, a low-noise amplifier 103, a receive circuit 104, a receiving field intensity detection circuit 105, a multi frequency generation local oscillator section 106 for generating a plurality of frequencies, a transmit circuit section 107, which is a previous stage of the wideband transmit amplifier, and a condition holding circuit 108 for holding conditions for the transmit amplifier 101 to smooth in a wideband. The low-noise amplifier 103, the receive circuit 104, and the field intensity detection circuit 105 are receive circuit sections for actual communications and also detection circuits for transmit power.

The wideband transmit amplifier section 101 amplifies a signal output from the transmit circuit 107 and outputs it to a transmit terminal. The transmit circuit 107 here includes a circuit which outputs a digital base band signal including information to be transmitted, a circuit such as DA converter which converts the digital base band signal into an analog signal to output, and a demodulation circuit which receives a carrier wave from the local oscillator 106 and demodulates the transmit signal. Accordingly, the signal transmitted by the transmit circuit 107 is an analog signal demodulated by a predetermined frequency. The transmit amplifier 101 receives a transmit signal, which is the above-mentioned demodulated analog signal, from the transmit circuit 107. Therefore, the transmit amplifier 101 outputs a signal made by amplifying a high frequency signal demodulated by the carrier wave.

A 20 dB attenuator 120 is responsible for attenuating the power of the signal output from the transmit amplifier 101. This is because that as the signal output from the transmit amplifier 101 is amplified, the power of the signal must be attenuated Otherwise, there will be an influence on the receive circuits such as the low-noise amplifier 103, which are described later in detail. For example, it is necessary to prevent a signal with its power exceeding the acceptable level for the low-noise amplifier 103 from being input to the low-noise amplifier 103.

The low-noise amplifier 103 has a function to amplify the attenuated signal, which is input via the abovementioned 20 dB attenuator 120, at a predetermined gain. Especially in this embodiment, the low-noise amplifier 103 is also responsible for amplifying weak noise such as thermal noise which flows into the receive circuits including the low-noise amplifier 103, the receive circuit 104 and the field intensity detection circuit 105 via a noise source 126 (for example a resistor), and checking the noise level of the corresponding receive circuits.

The receive circuit 104 includes a demodulation circuit which receives a high frequency analog signal output from the low-noise amplifier 103, a decoding circuit which performs a decoding process and a logical circuit which performs a predetermined process to a decoded digital base band signal. The receive circuit 104 outputs the analog signal before being converted into the digital base band to the field intensity detection circuit 105. The field intensity detection circuit 105 detects a peak voltage value of the received analog signal and outputs a VAC0, which is a digitalized peak voltage value having several bits.

The condition holding circuit 108 receives a fsel signal, which is a control signal for switching an oscillation frequency of the local oscillator 106, while receiving the VAC0. The fsel signal here is a signal output from a predetermined controller, for example a 2 bits digital signal. If there are 3 kinds of frequencies to hop, by using the 2 bits signal as the fsel, the predetermined controller can set the oscillation frequency of the local oscillator 106.

The condition holding circuit 108 has a storage device inside, such as a latch circuit, in order to store the values of the fsel and the VAC0. Further, the condition holding circuit 108 has a calculation section inside in order to calculate a value VAC1 according to the information stored in the abovementioned storage device. The calculated VAC1 is output to the transmit amplifier 101. The VAC1 here is a value which controls a resistance value of a variable resistor included in transmit amplifier 101.

The transmit amplifier 101 has an amplifier circuit section including a transistor M1, a capacitor C1, a resistor R1 and a bias power supply VB, a variable inductor 110 and a matching circuit 111. The transistor M1 amplifies an AC signal, which is input to a gate terminal, to gm(f) times a drain current. The capacitor C1 and the resistor R1 which are connected to the gate of the transistor M1 remove a DC component of the input AC signal. A DC voltage of the bias power supply VB is biased to the gate in order to obtain a desired gm(f). The variable inductor 110 plays a role of a load for performing a voltage conversion of the drain current to generate an amplified signal. The matching circuit 111 matches the impedance so as to suppress the attenuation of the amplified signal, which is generated by the variable inductor 110. Further, the power supply 112 supplies a voltage VDD to the transistor M1.

The loopback circuit 102 includes the attenuator 120, switches SW1 to SW5 for switching transmission and feedback and the noise source 126.

In the present invention, as shown in FIG. 1, the variable inductor 110 (inductance value Lv) is included in an output stage of the transmit amplifier 101 to vary the inductance Lv, so as to suppress the frequency deviation of the output power of the transmit amplifier 101. The variable inductor 110 is composed of a transformer. A mutual inductance M changes by varying a variable resistor Rv, which is connected in parallel with a coil L0 of an input side. As a result, the inductance value Lv of the coil L1 in the output stage changes. The transmit power can be adjusted by adjusting the inductance value Lv together with the output matching circuit 111.

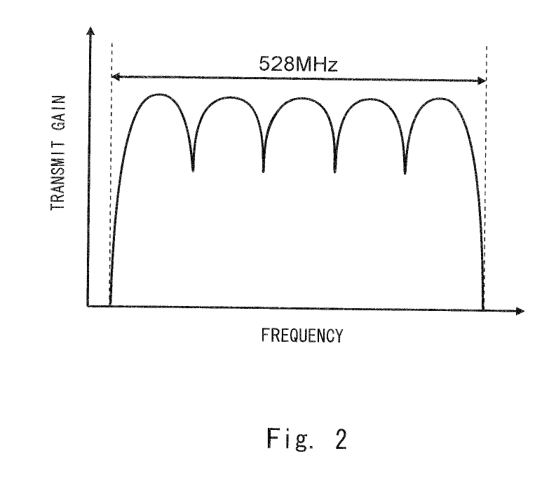

It is noted that in UWB, an accurate impedance matching is not necessary, which has been performed by narrowband systems. Thus the adjustment by the matching circuit 111 is not necessary for 1 to 2 GHz. In a narrowband system, an inaccurate impedance matching extremely deteriorates the transmit power in a notch as in FIG. 2. On the other hand, as UWB has wide bandwidth, the average transmit power does not largely change even with the characteristic shown in FIG. 2.

The transmit power smoothing is described hereinbelow using the formulas. Firsts the approximate formula of an output power Po in the transmit terminal is described below. The power at this time is assumed to be 50O matching.

Po^{˜}Ptx×gm(f)×2pf×Lv−Gl(f) (1)

where
Ptx: Power in conversion of 500 matching in transmit circuit output
gm(f): Frequency characteristic of a conductance gm of M1
Lv: Inductance value of the variable inductor 110
Gl(f): Frequency characteristic of a loss generated in a transmit amplifier and a matching circuit.

The approximate formula of the variable inductance Lv viewed from the matching circuit is described below.

Lv^{˜}L1−L0×[(ωK)²×L1×L0/{(ωL0)²+Rv²}] (2)

where

K=M/v(L1×L0)

M: Mutual inductance

By changing the variable resistance value Rv according to the frequency f and adjusting the inductance value Lv by the above formulas (1) and (2), the output power Po can be adjusted.

Next, detection and correction methods of the transmit output power are described. First, in order to detect an output power of the transmit amplifier 101, a variation is removed in each frequency of the power of a receive signal in the receive circuits including the 20 dB attenuator 120, the low-noise amplifier 103, the receive circuit 104 and the field intensity detection circuit 105. As the frequency of the output signal from the transmit amplifier 101 hops in the multiband OFDM, the variation in the power of an output signal in each frequency must be removed.

Therefore, SW2 and SW3 are turned on, let a signal output from the transmit amplifier 101 pass through the receive circuits with a different frequency, and the power of the signal in each frequency is analyzed. The details are described later. Then, a VAC0 of each frequency is computed to adjust the gain of the transmit amplifier 101 by each frequency according to the VAC0. In order to perform this adjustment appropriately, it is necessary to understand frequency dependence of the abovementioned receive circuits. If the power of the signal, which passes through the low-noise amplifier 103 and the receive circuit 104 to be output to the field intensity detection circuit 105, varies according to frequency dependence of the components of the receive circuits, it is not possible to appropriately evaluate the power which is output from the transmit amplifier 101 without figuring out the variation. Therefore, the frequency deviation of the power of the signal passing through the receive circuits is evaluated in advance.

Therefore, the switches SW1, SW2 and SW4 in the loopback circuit 102 are turned off and the switches SW3 and SW5 are turned on. Then, an input of the low-noise amplifier 103 and the noise source 126 are made to be conductive via the 20 dB attenuator 120. This makes weak noise such as thermal noise input to the low-noise amplifier 103 via SW5, the 20 dB attenuator and SW3. The low-noise amplifier 103 amplifies the received weak noise to output it to the receive circuit 104. Consequently, it is possible to evaluate including noise such as thermal noise.

Then, the frequency of the multi frequency generation local oscillation circuit section 106 is switched according to the frequency switching terminal fsel. To hope the frequency of the output signal from the transmit terminal by 3 kinds of frequencies, the local oscillator 106 supplies signals of each frequency to hop to the receive circuit 104.

The receive circuit 104 mixes the signal received from the low-noise amplifier 103, which is the amplified noise and signal received from the local oscillator 106, by a mixer included inside. Then, the receive circuit 104 outputs each frequency to hope and the mixed signal to the field intensity detection circuit 105. This enables to evaluate the frequency dependence of the signal output from the low noise amplifier 103. Further, the receive circuit 104 may outputs an output signal from a functional circuit, which is necessary for the processes to receive, to the field intensity detection circuit 105. Then the frequency dependence of the functional circuit included inside the receive circuit 104 can be evaluated.

The field intensity detection circuit 105 here outputs a VAC0 corresponding to each signal with a frequency to the condition holding circuit 108. The condition holding circuit 108 relates, for example, the values of a fsel and the VAC0 and store it in the internal storage device. For example, the condition holding circuit 108 stores the value of a fsel indicating a first frequency and the value of a VAC0 corresponding the first frequency. The holding circuit 108 stores VAC0 similarly for a second and a third frequencies. By the storage device storing those values, the condition holding circuit 108 is able to figure out the extent of the variation in the VAC0 according to the frequency of signals received by the receive circuit 104, which is the frequency to hop. That is, the condition holding circuit 108 is able to figure out frequency dependence of the components in the receive circuits.

Next, in order to start the operation for detecting an output level of the transmit amplifier 101, the switches SW2 and SW3 in the loopback circuit 102 are turned on to be conductive with the receive side. The other switches SW1, SW4 and SW5 are turned off. It is noted that the switches SW1 to SW5 are composed of, for example, MOSFET. A channel is formed from a source and to a drain in response to a gate voltage supplied from a control circuit so as to control the conducting status.

First, the condition holding circuit 108 determines an initial value of the VAC1, and then outputs the initial value to the variable resistor Rv included in the variable inductor 110. Then, the value of the variable resistor Rv changes to a value based on the initial value. This makes the inductance value Lv of the variable inductor change, and power of the signal output from the transmit amplifier 101 changes as indicated by the abovementioned formula. On the other hand, the controller adjusts the value of the fsel and controls the local oscillator 106 so that the local oscillator 106 outputs a signal having the first frequency to the transmit circuit 107. Further, the fsel is input also to the condition holding circuit 108. The condition holding circuit 108 writes the value of the fsel to the internal storage device. The signal output from the transmit circuit 107 has the first frequency, and the signal output from the transmit amplifier 101 also has the first frequency.

Next, the signal output from the transmit amplifier 101 is input to the low noise amplifier 103 via SW2, the 20 dB attenuator 120 and SW3. The low noise amplifier 103 amplifies the signal having the first frequency, which is output from the transmit amplifier 101, to the receive circuit 104. The receive circuit 104 branches the signal output from the low noise amplifier 103 and outputs it to the field intensity detection circuit 105. The field intensity detection circuit 105 calculates a peak value of a wave pattern of the received signal, and encodes the calculated peak value to a digital value so as to obtain a VAC0. Then, the field intensity detection circuit 105 outputs the obtained VAC0 to the condition holding circuit 108.

The condition holding circuit 108 writes the value of the VAC0 to the storage device. The calculation section inside the condition holding circuit 108 accesses the storage device to read out the VAC0 in order to check if the VAC0 is a desired power value. Then, if the VAC0 is not the desired power value, the calculation section determines a next VAC1 to output to the variable resistor, in consideration of the frequency dependence of the signal power concerning the first frequency of the receive circuits. The condition holding circuit 108 recognizes the frequency dependence in advance. Next, the condition holding circuit 108 outputs the new VAC1 determined by the calculation section to the variable resistor.

The above process is repeated until VAC0 indicates the desired power value. In other words, the condition holding circuit 108 repeats outputting VAC1 and obtaining VAC0. Then, if a transmit signal having the first frequency has the desired power value, the condition holding circuit 108 terminates adjusting the power value for the transmit signal having the first frequency.

Next, the condition holding circuit 108 outputs the initial value of the VAC1 so as to adjust the next frequency to hope, that is the power value of a transmit signal having a second frequency. At this time, the controller adjusts the value of the fsel and outputs the adjusted fsel value to the local oscillator 106 and also to the condition holding circuit 108. The local oscillator 106 outputs a signal having the second frequency to the transmit circuit 107.

Then, same processes to the adjustment of the transmit signal having the first frequency is performed. That is, firstly the field intensity detection circuit 105 outputs a VAC0 concerning the initial value of a VAC1 to the condition holding circuit 108. The calculation section inside the condition holding circuit 108 checks if the VAC0 indicates the desired power value. If the VAC0 is not the desired power value, the calculation section inside the condition holding circuit 108 determines a next VAC1 to output to the variable resistor, in consideration of the frequency dependence of the signal power concerning the second frequency of the receive circuits. The condition holding circuit 108 repeats to determine a VAC and obtain a VAC0 until the transmit signal having the second frequency becomes to have the desired power value. If the transmit signal having the second frequency becomes to have the desired power value, specifically if the power value of the transmit having the second frequency becomes almost the same as the power value of the transmit signal having the first frequency, the adjustment of the power value of the transmit signal having the second frequency is terminated.

Similarly, the power value of the transmit signal having a third frequency is adjusted. If the power value of the transmit signal having the third frequency becomes almost the same as the power value of the transmit signal having the first frequency, the adjustment of the power value of the transmit signal having the third frequency is terminated.

The deviation stored in the condition holding circuit 108 upon a transmission is interlocked with the frequency switching signal fsel, output to the variable resistor Rv as the control voltage VAC1 so as to vary the resistance value Rv. The inductance value Lv of the variable inductor 110 is increased by increasing the control voltage VAC1 to increase the variable resistance Rv. On the contrary, the inductance value Lv of the variable inductor 110 is decreased by decreasing the control voltage VAC1 to decrease the variable resistance Rv. The abovementioned control sets an optimal inductance value Lv for each frequency. This enables to suppress the deviation in the transmit power of each frequency at the time of transmission.

In the present invention, as a circuit necessary for detecting the transmit power of the transmit amplifier 101, there is only a small sized loopback circuit 102 and the condition holding circuit 108, except the existing receive circuit. That is, only the variable inductor 110 and the previously mentioned loopback circuit 102 are added to an analog circuit. Thus the increase in the circuit size can be suppressed to about ¼ as compared to Japanese Unexamined Patent Application Publication No. 11-074803. In Japanese Unexamined Patent Application Publication No. 11-074803, the transmit signal line includes an attenuator, thereby consuming the power more than necessary. On the other hand, in the present invention, the output power is optimized by adjusting the inductance value Lv of the variable inductor 110 of an output stage. As the detection circuit side does not consume power at the time of transmission, the power consumption can be reduced.

### Second Exemplary Embodiment

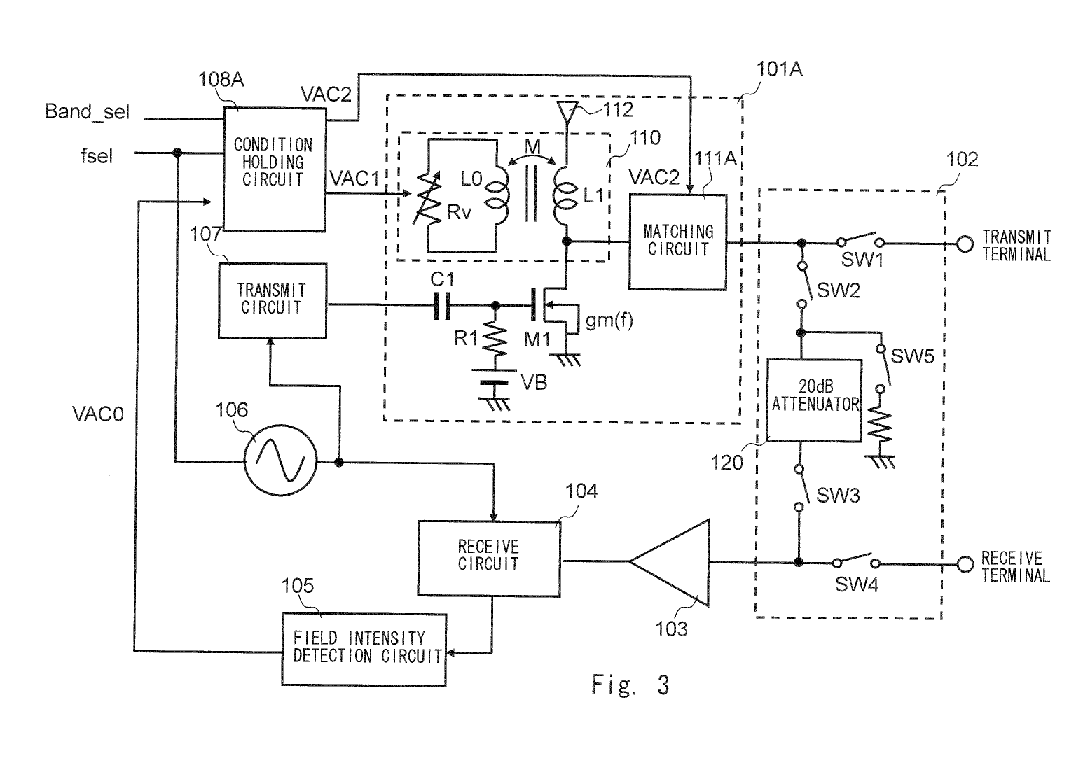

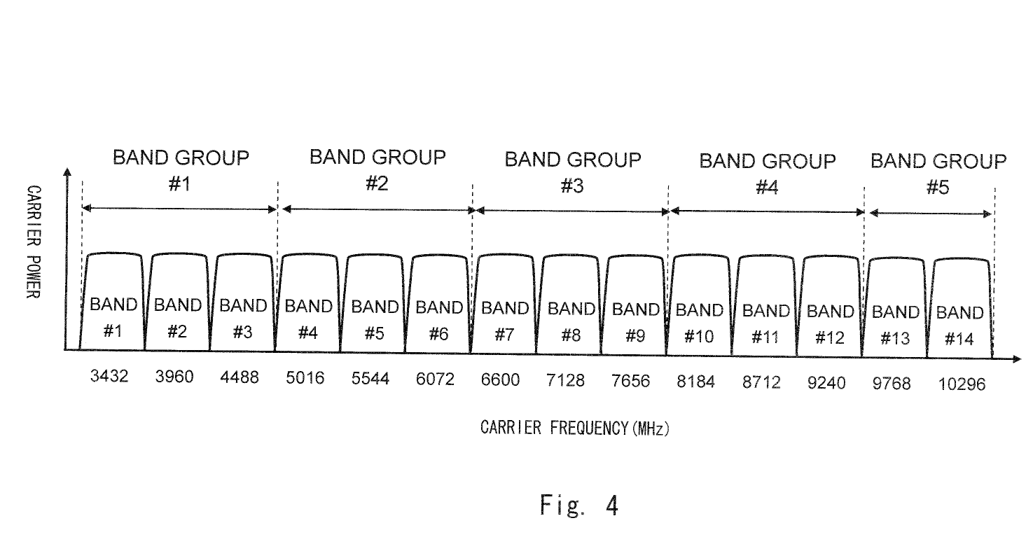

FIG. 3 is a block diagram illustrating a transmit/receive circuit for UWB including the transmit circuit according to the second exemplary embodiment of the present invention. The first embodiment is most suitable for a frequency hopping in each band group in the UWB system as shown in FIG. 4. On the other hand, in order to cover all frequency bands of UWB, the circuit should have the configuration of FIG. 3. In order to optimize for each frequency band group, a variable control function is provided to a matching circuit 111A of a transmit amplifier 101A, and a control terminal VAC2 for switching a setting value is included. Further, a condition holding circuit 108A includes a control terminal Band_Sel for selecting each frequency band group and performs a variable control of the matching circuit 111A by the control output terminal VAC2 which interlocks the abovementioned Band_sel.

As described above, many circuits used in actual communications are used to detect a frequency deviation of transmit power in the present invention. Further, frequency deviation can be suppressed by a variable inductor device. Therefore, the present invention provides a wideband transmit amplifier which is able to smooth transmit power with small circuit size.

Specifically, circuits necessary for detecting an output level of the transmit amplifier are only the loopback circuit 102 and the condition holding circuit 108, in addition to the existing receive circuit. That is, only the variable inductor 110 and the loopback circuit 102 are added to the analog circuit. Accordingly, the circuit size can be made smaller than the Japanese Unexamined Patent Application Publication No. 11-074803.

In Japanese Unexamined Patent Application Publication No. 11-074803, the transmit signal line includes an attenuator, thereby consuming the power more than necessary. However in the present invention, as the inductance value Lv of the variable inductor 110 of the output stage is adjusted to be optimal so as to optimize the output power, it is possible to suppress frequency deviation without increasing the power consumption. Further, the power consumption of the detector circuit will not increase as the power consumption of the detector circuit side (the low noise amplifier 103, the receive circuit 104 and the field intensity detection circuit 105) is in OFF state at the time of transmission.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A communication apparatus comprising:
an amplifier circuit which adjusts transmit power of a first signal and transmit power of a second signal if the transmit power of the first signal having a first frequency included in a first frequency band is different from the transmit power of the second signal having a second frequency included in a second frequency band, the second frequency being different from the first frequency,
wherein the amplifier circuit comprises a variable inductor which varies an inductance value for each of the first signal and the second signal to adjust the transmit power of the first signal and the transmit power of the second signal.

2. The communication device according to claim 1, wherein the variable inductor comprises:
a variable resistor which varies a resistance value for each of the first signal and the second signal;
a primary coil connected in parallel with the variable resistor; and
a secondary coil electromagnetically coupled to the primary coil.

3. The communication device according to claim 2, wherein the amplifier circuit further comprises a transistor which is connected in series with the secondary coil and has a gate input with a signal having the first frequency or the second frequency.

4. The communication device according to claim 1, wherein the amplifier circuit smoothes the transmit power of the first signal, the transmit power of the second signal and transmit power of a third signal having a third frequency included in a third frequency band, the third frequency being different from the first frequency and the second frequency, and
the variable inductor varies an inductance value for each of the first to the third signals to smooth the transmit power of the first to the third signals.

5. The communication device according to claim 2, wherein the amplifier circuit smoothes the transmit power of the first signal, the transmit power of the second signal and transmit power of a third signal having a third frequency included in a third frequency band, the third frequency being different from the first frequency and the second frequency, and
the variable inductor varies an inductance value for each of the first to the third signals to smooth the transmit power of the first to the third signals.

6. The communication device according to claim 3, wherein the amplifier circuit smoothes the transmit power of the first signal, the transmit power of the second signal and transmit power of a third signal having a third frequency included in a third frequency band, the third frequency being different from the first frequency and the second frequency, and
the variable inductor varies an inductance value for each of the first to the third signals to smooth the transmit power of the first to the third signals.
